(19) United States
(12) Patent Application Publication
(10) Pub. No.: US 2007/0072404 A1
(43) Pub. Date: Mar. 29, 2007

(54) Phase-change optical disk

(75) Inventor: Eiji Kariyada, Tokyo (JP)

Correspondence Address: FOLEY AND LARDNER LLP;SUITE 500, 3000 K STREET NW, WASHINGTON, DC, 20007, US

(73) Assignee: NEC CORPORATION

(21) Appl. No.: 11/528,594

(22) Filed: Sep. 28, 2006

(30) Foreign Application Priority Data
Sep. 29, 2005 (JP) 2005-283680

(51) Int. Cl. H01L 21/28; H01L 21/3205

(52) U.S. Cl. 438/602; 438/603

(57) ABSTRACT

A phase-change optical disk includes a layer structure including a ZnS—SiO₂ first dielectric layer, an oxynitride second dielectric layer including SiHfON, a ZnS—SiO₂ third dielectric layer, a GeN interface layer, a Ge₂Sb₂Te₅ recording layer, a GeN interface layer, a ZnS—SiO₂ dielectric layer, and a reflective layer, which are consecutively deposited on a transparent substrate. The relationship between refractive indexes of the first through third dielectric layers allows the optical absorption rate in the amorphous state of the recording layer to be lower than in the crystal state thereof.

### BACKGROUND OF THE INVENTION

(a) Field of the Invention

The present invention relates to a phase-change optical disk and, more particularly, to a phase-change optical disk in which data is stored and erased by changing a spot of the optical disk between a crystal phase and an amorphous phase, and from which data is reproduced by distinguishing the phase of the spot of the optical disk.

(b) Description of the Related Art

Optically recording/reproducing data by using a laser beam has been intensively used in the field of data storage because of the advantage of high-speed, large-capacity and non-contact recording/reproducing capability. Examples of the optical disk used in the optical recording/reproducing scheme include a compact disk (CD) and a laser disk, and are categorized into read-only (ROM) disk, write-once (RO) disk, and rewritable (RW) disk. The ROM disk is dedicated to use of reading the stored data, the RO disk is such that the user data can be stored once in a new disk, and the RW disk is such that the user can store and erase the user data for a number of times. The RO and RW disks are generally used as external memory devices for a computer system to store therein document files and/or image files.

The RW optical disks include a phase-change optical disk using the phase change of the recording layer, and a magneto-optical disk using the change of direction in the magnetization. The phase-change optical disk, which does not use an external magnetic field for recording data in the disk and is easy to overwrite the data therein, has become the mainstream of the optical recording/reproducing media.

In a conventional phase-change optical disk, the optical absorption rate (Aa) of the amorphous phase of the recording layer is generally higher than the optical absorption rate (Ac) of the crystal phase of the recording layer. In this case, a recorded mark formed as an amorphous-phase mark on the recording layer by irradiating a spot of the recording layer may absorb the laser beam at a higher absorption rate than the unrecorded area of a crystal phase. This may cause a failure wherein the recorded mark on a recording track erroneously assumes a crystal phase during recording data on an adjacent track, which failure is generally referred to as a cross-erasure. The cross-erasure is especially critical in a phase-change optical disk having a higher recording density because of a narrow recording track formed on the recording layer.

For prevention of the cross-erasure, it is effective to set the optical absorption rate (Aa) of the recorded mark of an amorphous phase to be lower than the optical absorption rate (Ac) of the unrecorded area of a crystal phase. A proposal for obtaining such a relationship, Aa<Ac, uses a phase-change optical disk having a first dielectric layer, a second dielectric layer, a third dielectric layer, a first interface layer, a recording layer, a fourth dielectric layer and a reflective layer, which are consecutively formed on a substrate, wherein the relationship n2<n3 and n2<n1 holds, given n1, n2, n3 being the refractive indexes of the first through third dielectric layers, respectively.

In a concrete example of the configuration of the proposed optical disk, the first and third dielectric layers are made of ZnS—SiO₂ having a refractive index of 2.3 (i.e., n1=n3=2.3), and the second dielectric layer is made of SiO₂ having a refractive index of 1.5 or made of Al₂O₃ having a refractive index of 1.7 (i.e., n2=1.5 or 1.7). The second dielectric layer may be made of SiN having a refractive index of 1.9 instead. Such a configuration is described in Patent Publications JP-2000-90491A, and -105946A, for example.

If SiO₂ or Al₂O₃ is used for the material of the second dielectric layer, a sputtering technique is generally employed using a SiO₂ or Al₂O₃ target. However, the SiO₂ or Al₂O₃ film formed by the sputtering technique has a lower through-put in the deposition. On the other hand, if SiN having a refractive index as high as around 1.9 is used for the material of the second dielectric layer, the fourth dielectric layer should have a larger thickness due to the higher refractive index of the second dielectric layer, although the deposition rate of SiN is larger than the deposition rate of SiO₂ and Al₂O₃. The larger thickness of the fourth dielectric layer may degrade the overwrite resistance of the optical disk.

A literature, “Proceedings of the 16th Symposium on Phase Change Optical Information Storage PCOS2004”, pp. 57-62 (2004) describes use of an oxynitride second dielectric layer, i.e., SiNiON layer deposited using a SiNi target including Si as a main component and Ni as an additive component under a mixed gas atmosphere including argon, oxygen and nitrogen. The resultant SiNiON layer formed as the second dielectric layer has a higher deposition rate and a relatively lower refractive index, thus allows a smaller thickness for the fourth dielectric layer, and achieves a higher overwrite resistance of the optical disk compared to the case of using a SiO₂ or Al₂O₃ film.

The SiNiNO layer described in the above literature, however, has the problem that since the SiNi target has a specific resistance as high as 5 to 10 Ω-cm, the sputtering of SiNi should use a RF sputtering for dealing with the higher specific resistance. However, the RF sputtering often incurs an abnormal discharge, whereby a stable sputtering is difficult to achieve.

A pulse DC sputtering technique has been increasingly used for forming other films due to the advantage of a higher deposition rate of the resultant film. The pulse DC sputtering technique generally necessitates use of a target material having a specific resistance of 1 Ω-cm or above. Thus, it is difficult to use the SiNi target in the pulse DC sputtering process.

### SUMMARY OF THE INVENTION

In view of the above problems in the conventional techniques, it is an object of the present invention to provide a phase-change optical disk having an oxynitride dielectric layer which is capable of being deposited using the pulse DC sputtering technique.

It is another object of the present invention to provide a method for forming an oxynitride dielectric layer by using the pulse DC sputtering technique.

The present invention provides, in a first aspect thereof, a phase-change optical disk including a substrate, and a layer structure overlying the substrate and including an oxynitride dielectric layer and a recording layer, wherein the oxynitride dielectric layer includes an oxynitride substance including silicon as a main component thereof and at least one additive element selected from the group consisting of Hf, Mn, Fe, Nb, Mo, Al, W and Ag.

The present invention provides, in a second aspect thereof, a method for manufacturing a phase-change optical disk including forming a layer structure including a oxynitride dielectric layer and a recording layer on a substrate, wherein: forming the oxynitride dielectric layer is performed by a reactive-ion sputtering in a mixed gas atmosphere including argon, oxygen and nitrogen; and the reactive-ion sputtering uses a target including silicon as a main component thereof and at least one additive element selected from the group consisting of Hf, Mn, Fe, Nb, Mo, Al, W and Ag.

The present invention provides, in a third aspect thereof, a method for manufacturing a phase-change optical disk including consecutively: forming a first dielectric layer overlying a transparent substrate; forming an oxynitride dielectric layer on the first dielectric layer by using a reactive-ion sputtering in a mixed gas atmosphere including argon, oxygen and nitrogen; and consecutively forming, on the oxynitride layer, a second dielectric layer, a recording layer, a third dielectric layer, and a reflective layer, wherein the reactive-ion sputtering uses a target including silicon as a main component thereof and at least one additive element selected from the group consisting of Hf, Mn, Fe, Nb, Mo, Al, W and Ag.

The present invention provides, in a fourth aspect thereof, a method for manufacturing a phase-change optical disk including: consecutively forming a reflective layer, a first dielectric layer, a recording layer, and a second dielectric layer to overlie a substrate; forming an oxynitride dielectric layer on the second dielectric layer by using a reactive-ion sputtering in a mixed gas atmosphere including argon, oxygen and nitrogen; and consecutively forming a third dielectric layer and a transparent film on the oxynitride dielectric layer, wherein the reactive-ion sputtering uses a target including silicon as a main component thereof and at least one additive element selected from the group consisting of Hf, Mn, Fe, Nb, Mo, Al, W and Ag.

In accordance with the optical disk of the present invention, since the oxynitride dielectric layer has a refractive index equivalent to the refractive index of a SiO₂ or SiNiON layer and has a deposition rate higher than the deposition rate of the SiO₂ and SiNiON layers, the optical disk having a suitable characteristic can be manufactured at a higher through-put.

In accordance with the method of the present invention, the reactive-ion sputtering achieves a higher deposition rate compared to the RF sputtering in the case of a lower specific resistance of the target used in the sputtering. The target including the element selected from the group as an additive element reduces the specific resistance of the target, thereby achieving a higher through-put in the reactive-ion sputtering and thus manufacturing the optical disk. The reactive-ion sputtering may be performed as pulse DC sputtering.

The above and other objects, features and advantages of the present invention will be more apparent from the following description, referring to the accompanying drawings.

### BRIEF DESCRIPTION OF THE DRAWINGS

FIG. 1 is a sectional view of an optical disk according to a first embodiment of the present invention.

FIG. 2 is a graph showing the relationship between the content of additive O₂ in the mixed gas and the deposition rate of a SiHfON layer.

FIG. 3 is a graph showing the relationship between the content of additive O₂ in the mixed gas and the refractive index of the SiHfON layer.

FIG. 4 is a graph showing the relationship between the refractive index of the SiHfON layer and the content of additive elements in the SiHfON layer.

FIG. 5 is a graph showing the relationship between the refractive index of the SiHFNO layer and the density thereof.

FIG. 6 is a graph showing the relationship between the content of additive O₂ in the mixed gas and the deposition rate as well as the refractive index of a SiHfO layer.

FIG. 7 is a ternary diagram of Ar, O₂ and N₂ for showing the range of composition of the mixed gas which provides a desirable oxynitride dielectric film.

FIG. 8 is a graph showing the additive-O₂-content dependency of the deposition rate of the SiHfON film formed by pulse DC sputtering and the SiNiON layer formed by RF sputtering.

FIG. 9 is a graph showing the additive-O₂-content dependency of the refractive index of the SiHfON layer and the SiNiON layer.

FIG. 10 is a graph showing the relationship between the content of additive Nb in a target and the content of additive Nb in the sputtered SiNbON film.

FIG. 11 is a graph showing the relationship between the content of additive N EL and additive Hf element in a Si-base target and the specific resistance of the resultant target.

FIG. 12 is a sectional view of an optical disk according to a second embodiment of the present invention.

### PREFERRED EMBODIMENT OF THE INVENTION

Now, the present invention is more specifically described with reference to accompanying drawings.

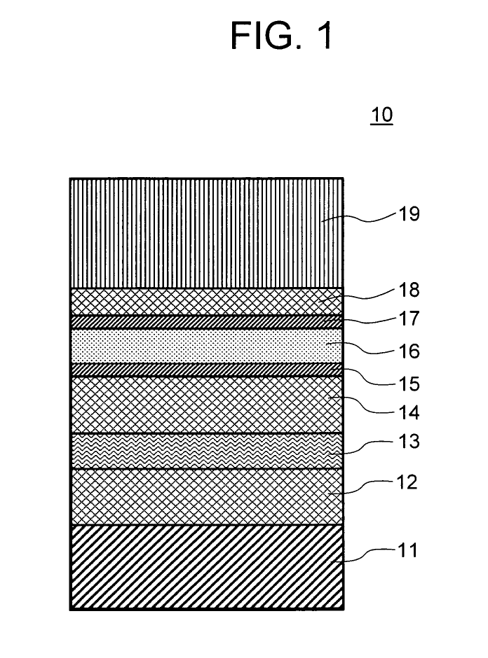

FIG. 1 shows a schematic sectional structure of a phase-change optical disk according to a first embodiment of the present invention. The optical disk, generally designated by numeral 10, includes a transparent substrate 11, and a layer structure including a first dielectric layer 12, an oxynitride dielectric layer 13, a second dielectric layer 14, a first interface layer 15, a recording layer 16, a second interface layer 17, a third dielectric layer 18 and a reflective layer 19, which are consecutively deposited on the transparent substrate 11. Another transparent substrate or a transparent film (not shown) is bonded onto the reflective layer 19. Each of the above recited layers may be a single-film layer or a multiple-film layer.

The first, second and third dielectric layers 12, 14, 18 are made of ZnS—SiO₂, for example. The oxynitride dielectric layer 13 is made of oxynitride silicon hafnium (SiHfON), in this example. The oxynitride dielectric layer or SiHfON layer 13 is deposited using a reactive-ion sputtering technique, and includes 39-67.5 at. % oxygen. For example, the first and second interface layers 15, 17 are made of GeN, the recording layer 16 is made of Ge₂Sb₂Te₅, the reflective layer 19 is made of AlTi, and the another transparent substrate is 0.6 mm thick.

The recording layer 16 has an optical absorption rate Aa in the amorphous phase thereof, which is lower than the optical absorption rate Ac in the crystal phase. For achieving the relationship Aa<Ac, the layers of the layer structure must have a specific relationship between the respective refractive indexes. First, the transparent substrate 11 made of plastic, resin or glass has a refractive index of 1.5-1.6, and the first dielectric layer 12 formed thereon must have a refractive index higher than the refractive index of the transparent substrate 11.

That is, the first dielectric layer 12 having a refractive index substantially equal to the refractive index of the transparent substrate 11 cannot achieve the above relationship Aa<Ac because such a relationship allows the first dielectric layer 12 to have an optical characteristic equivalent to the optical characteristic of the transparent substrate 11. In addition, the first dielectric layer 12 should have a suitable adhesiveness with respect to the transparent substrate 11. Thus, the first dielectric layer 12 as well as the second and third dielectric layer 14, 18 is made of ZnS—SiO₂ in the present embodiment.

The ZnS—SiO₂ layers have a refractive index of around 2.35 which is significantly higher than the refractive index (1.5-1.6) of the transparent substrate 11. The oxynitride dielectric layer 13 includes an oxynitride substance including silicon (Si) as a main component thereof and at least one additive element selected from the group consisting of Hf, Mn, Fe, Nb, Mo, Al, W and Ag, and the content of additive element or elements is between 0.2 at. % and 10 at. %.

The SiHfON layer configuring the oxynitride dielectric layer 13 in the present embodiment has a refractive index of around 1.43 to 1.8, whereby the relationship between the refractive index (n13) of the SiHfON layer and the refractive index (n14≈2.35) of the second dielectric layer satisfies n13<n14, and the relationship between n13 and the refractive index (n12≈2.35) of the second dielectric layer 12 satisfies n12>n13. These relationships together with the above configurations of the first dielectric layer 11 allow the optical absorption rate Aa of the recording layer 16 in the amorphous phase to be lower than the optical absorption rate Ac of the recording layer 16 in the crystal phase.

If the SiHfON layer configuring the oxynitride dielectric layer 13 has an oxygen content of 39 atomic percents (at. %) or lower, the SiHfON layer will have a higher refractive index to thereby necessitate a larger thickness of the third dielectric layer 18 in order for achieving the relationship Aa<Ac. The larger thickness of the third dielectric layer 18 may degrade the signal quality of the recorded mark after the iterated overwrite of the recording layer 16. This situation will be detailed later. On the other hand, if the SiHfON layer has an oxygen content of 67.5 at. % or higher, the SiHfON will have a lower deposition rate, to degrade the productivity of the optical disk. Thus, the SiHfON layer 13 should preferably have an oxygen content between 39 at. % and 67.5 at. %.

In a write operation of the optical disk of FIG. 1, the entire area of the recording layer 16 assumes a crystal phase in an initial state thereof. A recording laser beam is irradiated onto the optical disk 10 through the bottom surface thereof. The laser beam consecutively passes the transparent substrate 11, first dielectric layer 12, oxynitride dielectric layer 13, second dielectric layer 14 and first interface layer 15 to be incident onto the recording layer 16. The laser beam passed by the recording layer 16 then passes the second dielectric layer 17 and third dielectric layer 18 to be reflected by the reflective layer 19, and returns again to the recording layer 16. The returned laser beam heats the irradiated spot of the recording layer 16 up to or above the melting point of the recording layer 16, thereby melting the irradiated spot. The melted spot eventually assumes an amorphous phase after coagulation of the melted spot to thereby form a recorded mark.

For reproducing data from the recorded mark on the optical disk, the recording layer 16 is irradiated by a reproducing laser beam, to detect the reflectivity of the irradiated spot. More specifically, since the recorded mark assuming the amorphous phase has a higher reflectivity than the unrecorded area, the higher reflectivity of the recorded mark is detected by the reproducing laser beam to read the recorded data. Erasure of the recorded mark is performed by irradiating the recorded mark up to a specific temperature, which is higher than the crystallizing temperature and yet lower than the melting temperature, thereby converting the amorphous phase of the recorded mark into the crystal phase or unrecorded spot.

In manufacture of the optical disk of the present embodiment, the oxynitride dielectric layer 13 is deposited by a reactive-ion sputtering technique, whereby the oxynitride dielectric layer 13 is deposited at a higher deposition rate without involving degradation of the film density. That is, the SiHfON layer 13 has an excellent film quality.

A process for manufacturing the optical disk of FIG. 1 will be described hereinafter. The structure shown in this figure is obtained by using an in-line sputtering system, which deposits the above layers 12 to 19 consecutively by sputtering, on the transparent substrates one by one. The in-line sputtering system uses a distance of 15 cm, for example, between the substrate and the target to be sputtered.

The first dielectric layer 12 is deposited on the transparent substrate 11 by sputtering using a ZnS—SiO₂ target in an argon (Ar) gas atmosphere at a gas pressure of 0.1 Pa and a power density of 2.2 watts/cm², to obtain a thickness of 35 nm, for example.

The SiHfON layer 13 is then deposited on the first dielectric layer 12 by a pulse DC sputtering process using a target having a composition of Si₉₉Hf₁ (atomic percent) in a mixed gas atmosphere including Ar, N₂ and O₂ at a total pressure of 0.2 Pa and a power density of 2.5 watts/cm², to obtain a thickness of 40 nm, for example.

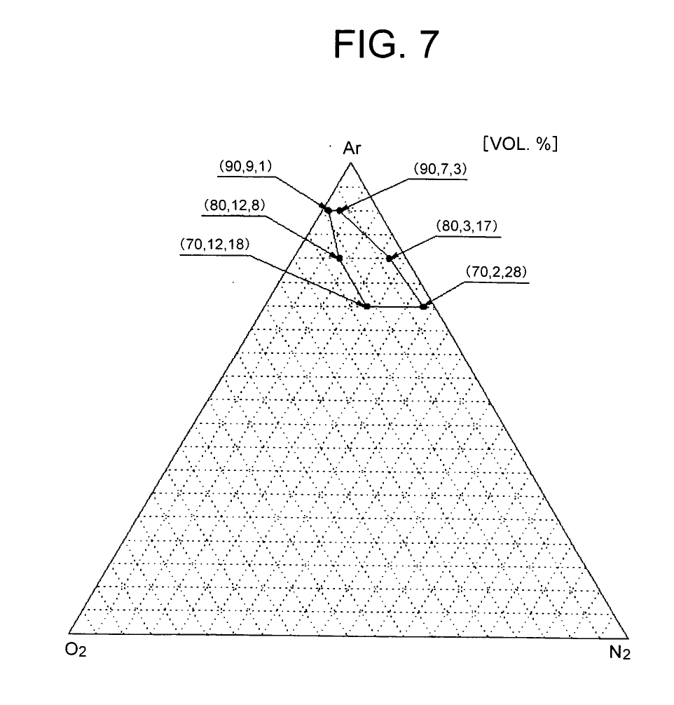

The mixed gas should include Ar, O₂ and N₂ in a composition defined on a ternary diagram by a hexagon having apexes of (90, 9, 1), (80, 12, 8), (70, 12, 18), (70, 2, 28), (80, 3, 17) and (90, 7, 3), and the internal of the hexagon, as shown in FIG. 7, all of the three values between the parentheses being expressed in terms of volume percents of Ar, O₂, N₂ in this order.

The second dielectric layer 14 is then deposited on the SiHfON layer 13 by sputtering using a ZnS—SiO₂ target in an Ar gas atmosphere at a gas pressure of 0.1 Pa and a power density of 2.2 watts/cm², to obtain a thickness of 30 nm, for example.

The GeN first interface layer 15 is then deposited on the second dielectric layer 14 by reactive-ion sputtering using a Ge target in a mixed gas atmosphere including Ar and N₂ at a gas pressure of 0.9 Pa and a power density of 0.8 watts/cm², to obtain a thickness of 5 nm, for example.

The Ge₂Sb₂Te₅ recording layer 16 is then deposited on the first interface layer 15 by sputtering using a Ge₂Sb₂Te₅ target in an Ar gas atmosphere at a gas pressure of 0.9 Pa and a power density of 0.27 watts/cm², to obtain a thickness of 13 nm, for example.

The GeN second interface layer 17 is then deposited on the recording layer 16 by sputtering using a Ge target in a mixed gas atmosphere at a gas pressure of 0.9 Pa and a power density of 0.8 watts/cm², to obtain a thickness of 5 nm, for example.

The third dielectric layer 18 is then deposited on the second interface layer 17 by sputtering using a ZnS—SiO₂ target in an Ar gas atmosphere at a gas pressure of 0.1 Pa and a power density of 2.2 watts/cm², to obtain a thickness of 25 nm, for example.

The reflective layer 19 is then deposited on the third dielectric layer 18 by sputtering using an Al—Ti alloy target including 2 wt. % Ti in an Ar gas atmosphere at a gas pressure of 0.08 Pa and a power density of 1.6 watts/cm², to obtain a thickness of 100 nm, for example, for the Al—Ti alloy layer.

Another transparent substrate or film (not shown) having a thickness of 0.6 mm is then attached and bonded onto the reflective layer 19, thereby achieving a phase-change optical disk 10 of the present embodiment.

The mixed gas used as the ambient gas for depositing the oxynitride dielectric layer 13 has the composition defined by the specific area of the ternary diagram shown in FIG. 7, and the internal thereof as described before. The reason of the specified composition will be described hereinafter with reference to a first example of the present embodiment.

### FIRST EXAMPLE

Samples of SiHfON layer in the optical disk 10 shown in FIG. 1 were manufactured as a first example for the first embodiment. During the manufacture, the composition of the ambient gas used in the reactive-ion sputtering for depositing the SiHfON layer was varied in the range of Ar gas content between 60 vol. % and 95 vol. %, additive O₂ gas content between zero vol. % and 12 vol. % and additive N₂ gas content between 1 vol. % and 40 vol. %. The target used therein was a Si₉₉Hf₁ target, and the gas pressure was fixed at 0.2 Pa.

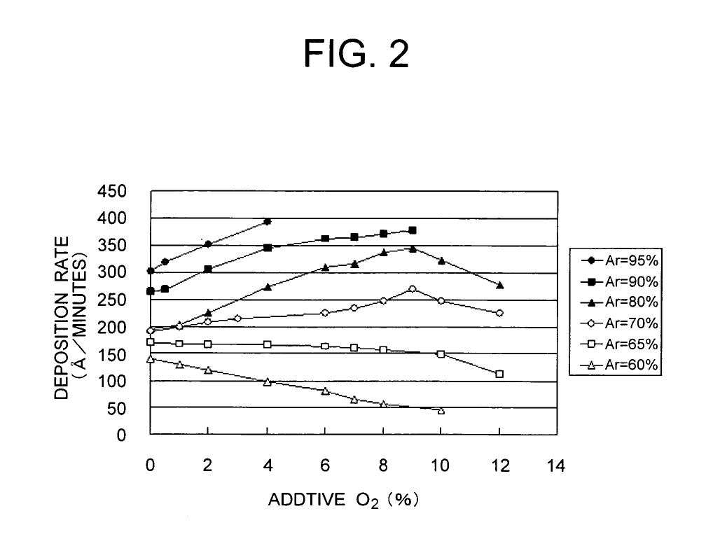

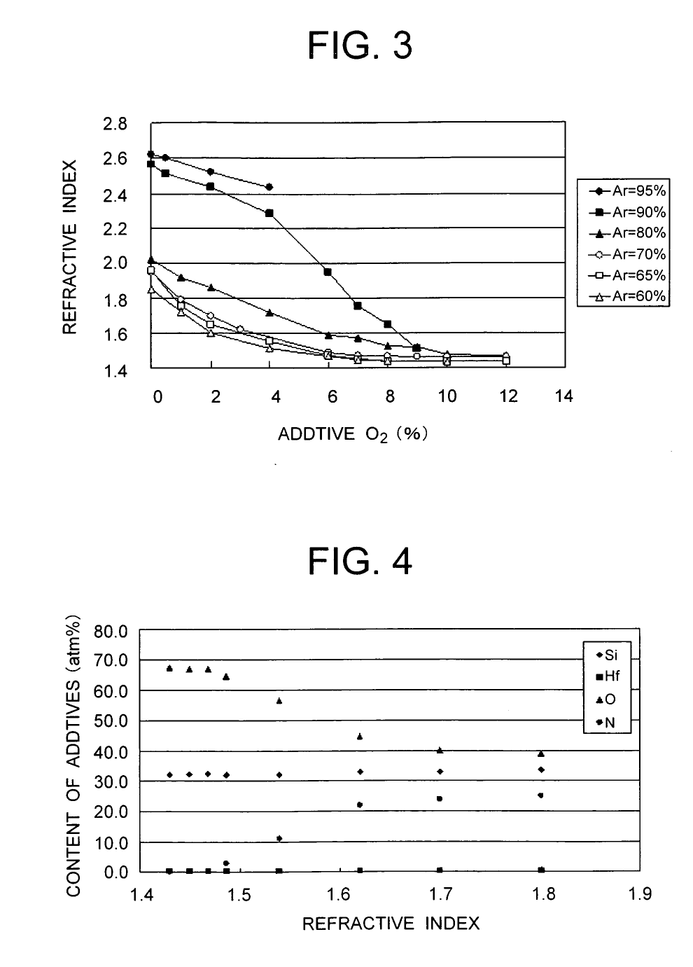

FIG. 2 shows the relationship obtained in the first example between the additive O₂ gas content in the mixed gas plotted on abscissa and the deposition rate of the SiHfON layer 13 plotted on ordinate. FIG. 3 shows the relationship obtained in the first example between the additive O₂ gas content and the refractive index of the SiHfON layer plotted on ordinate. FIG. 6 shows the relationship obtained in a comparative example between the additive O₂ gas content in the mixed gas and the deposition rate, the mixed gas including therein no N₂ content. It is to be noted in the graph of FIGS. 2 and 3 that the additive N₂ gas content, which is not specifically shown in FIGS. 2 and 3, is the remainder obtained by subtracting the additive O₂ and Ar gas contents from the total, i.e., 100%.

As understood from FIG. 2, increase of the O₂ gas content increases the deposition rate in the case of an Ar gas content of 70 vol. % or above. In addition, if the O₂ gas content is fixed, increase of the Ar gas content increases the deposition rate. On the other hand, increase of the O₂ gas content moderately decreases the deposition rate in the case of an Ar gas content of 65 vol. % or below.

It will be understood from FIG. 3 that increase of the O₂ gas content reduces the refractive index of the SiHfON layer, and that the refractive index has a tendency of assuming a lower value in the case of a lower O₂ gas content.

The refractive index required of the oxynitride dielectric layer 13 of the optical disk should be lower than the refractive index (2.35) of the ZnS—SiO₂ layer configuring the first and second dielectric layers 12, 14, with the difference between the refractive index of the oxynitride dielectric layer 13 and the refractive index of the first and second dielectric layers 12, 14 being preferably as larger as possible. The reason will be described hereinafter.

If the refractive index (n13) of the oxynitride dielectric layer resides within the range of 1.43 to 1.8, the thickness of the ZnS—SiO₂ third dielectric layer 18 satisfying the relationship Aa<Ac resides in a reasonable range between around 15 nm and 40 nm, and thus can be designed with ease. On the other hand, if the oxynitride dielectric layer 13 having a higher refractive index of 1.9 to 2.0 is used, the required thickness of the ZnS—SiO₂ third dielectric layer 18 satisfying the relationship Aa<Ac is significantly larger, and thus resides in a limited range between around 40 nm and 50 nm. Further, if the oxynitride dielectric layer 13 having a refractive index of 2.0 to 2.2 is used, the thickness of the third dielectric layer 18 satisfying the relationship Aa<Ac is extremely larger, and thus is out of the design range.

From the above analysis, the oxynitride dielectric layer 13 should preferably have a refractive index (n13) of 1.9 or lower. In addition, the deposition rate should be as large as possible in the view point of mass productivity.

Thus, the mixed gas satisfying the above conditions resides in the area of the hexagon defined by the apexes of (90, 9, 1), (80, 12, 8), (70, 12, 18), (70, 2, 28), (80, 3, 17) and (90, 7, 3) on the ternary diagram, wherein all of three values between the parentheses are expressed in terms of volume percents of Ar, O₂, N₂ in this order, as shown in FIG. 7. Most preferable mixed gas includes an additive O₂ content of 9 vol. % in the case of an Ar gas content of 70 to 90 vol. %, for achieving a highest deposition rate and a lower refractive index of the oxynitride dielectric layer 13.

The SiHfON layer deposited by the reactive-ion sputtering in the mixed gas atmosphere has a refractive index (n13) of 1.43 to 1.8. In the phase-change optical disk including such a SiHfON layer 13, the optical absorption ratio Aa in the crystal phase and the optical absorption ratio Ac in the amorphous phase were measured, to obtain the result that Aa=62.2% and Ac=82.4% in the case of n13=1.43, and Aa=60.2% and Ac=81.5% in the case of n13=1.8, thereby satisfying the relationship Aa<Ac in both the cases.

FIG. 4 shows the content (at. %) of Si, Hf, O and N in the SiHfON layers having different refractive indexes between 1.43 and 1.8. In FIG. 4, the SiHfON layers having a refractive index of 1.43 to 1.8 reveal that increase of the refractive index is associated with the increase of the oxygen content and decrease of the nitrogen content. Increase of the silicon content slightly increases the refractive index. The Hf content need not be varied for achieving different refractive indexes of the SiHfON layer.

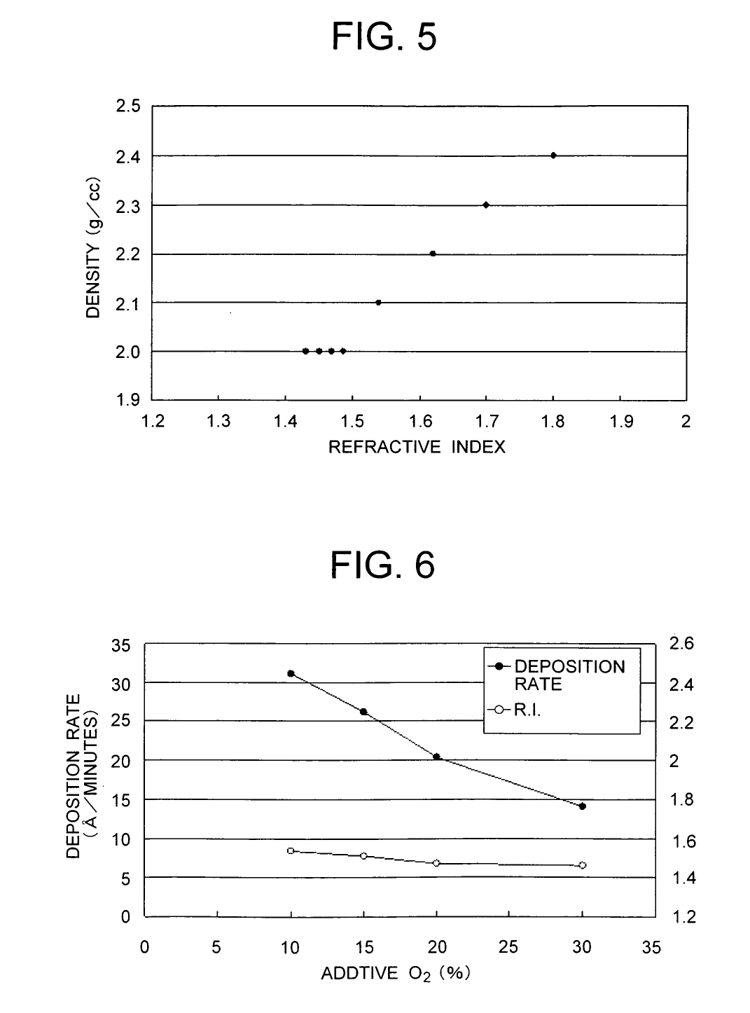

FIG. 5 shows a graph showing the relationship between the refractive index of the same SiHfON layer and the film density thereof. The film density of the SiHfON layer increases with the increase of the refractive index thereof. As will be understood from FIGS. 4 and 5, if the SiHfON layer deposited in the mixed gas atmosphere as described above has a refractive index (n13) of 1.43, the oxygen content and film density of the SiHfON layer are 67.5 at. % and 2 gram/cc, respectively. If the refractive index (n13) is 1.8, the oxygen content and film density of the SiHfON layer are 39 at. % and 2.4 gram/cc, respectively. If the SiHfON layer 13 has a refractive index in the above range, the thickness of the third dielectric layer 18 satisfying the above relationship Aa<Ac is 15 to 40 nm, and thus can be designed with a relatively wide design margin. More specifically, the process used in the first example to satisfy the above conditions provided an optical disk having an excellent overwrite characteristic and satisfying the relationship Aa<Ac without degradation of the productivity.

In the above analysis, the content of each element and the film density were measured by using a Rutherford backscattering spectrometry (RBS) and a nuclear reaction analysis (NRA).

Reliability of the phase-change optical disk 10 manufactured by the above process will be discussed hereinafter. The optical disk of the first example according to the first embodiment was rotated at a linear velocity of 5.9 meters/second, while irradiating the optical disk with a blue laser beam having a wavelength of 405 nm by using an optical head including an objective lens having a numerical aperture of 0.65. First, a data signal having a frequency of 4 MHz and d duty ratio of 50% was recorded on a specific land area of the optical disk. Then, a data signal having a frequency of 8 MHz and a duty ratio of 50% was iteratively recorded on the grooves disposed adjacent to and sandwiching therebetween the specific land area, and the change of the carrier of the data signal recorded on the specific land area and having a frequency of 4 MHz was measured.

The measurement revealed that the data signal recorded on the specific land area was not substantially changed after the iterated overwrite by the data signal on the adjacent grooves. The optical disk was further subjected to overwrite by a data signal having a frequency of 4 MHz and a duty ratio of 50%, revealing no change of carrier and noise until the overwrite was performed for 500,000 times.

A process of first comparative example was also performed using a mixed gas including no nitrogen content. FIG. 6 shows the result of the first comparative example, wherein the oxygen content in the mixed gas including Ar and O₂ is plotted on the abscissa and the deposition rate achieved by the mixed gas is plotted on the ordinate.

The reactive-ion sputtering used in the first comparative example provided a SiHfO layer. A pulse DC sputtering using a Si₉₉Hf₁ target was used as the reactive-ion sputtering, wherein the mixed gas included Ar and O₂ at a gas pressure of 0.2 Pa, the O₂ gas content was varied, a distance of 15 cm was employed between the target and the substrate, and a power density was 2.5 watts/cm².

As understood from FIG. 6, a SiHfO layer having a refractive index (R.I.) of around 1.45 to 1.54 was obtained in an O₂ gas content of 10 to 30 vol. %. However, the deposition rate was as low as 31.5 angstroms per minute or lower, which is extremely lower than the deposition rate (210 to 375 angstroms per minute) achieved in the mixed gas including Ar, O₂ and N₂. Although the refractive index satisfies the relationship Aa<Ac, this process is not suitable as a sputtering process used for a mass production due to the lower deposition rate.

As described above for the first comparative example, the sputtering process using a Si₉₉Hf₁ target, and a mixed gas including Ar and O₂ does not provide a suitable deposition rate for the oxide dielectric layer.

Next, a second comparative example using a mixed gas including nitrogen content and no oxygen content will be discussed. The reactive-ion sputtering using such a mixed gas provides a SiHfN layer instead of the oxynitride dielectric layer obtained by the first example. The second comparative example used a reactive-ion sputtering wherein a mixed gas included Ar gas, N₂ gas and no O₂ gas at a gas pressure of 0.2 Pa, and a Si₉₉Hf₁ target wherein the distance between the target and the substrate was 15 cm. The power density was 2.5 watts/cc. The mixed gas used in the second comparative example was such that the additive oxygen content in FIGS. 2 and 3 was fixed at zero. As understood from FIG. 3, an Ar gas content of 70 vol. % provides a SiHfN layer having a refractive index of 1.95 in the case of a zero oxygen content. As shown in FIG. 2 however, the deposition rate of this SiHfN layer is lower than the case of an O₂ content of 2 vol. % with the other conditions being the same, and thus the SiHfON layer in the present embodiment is superior to the SiHfN in the view point of mass productivity.

Next, a comparison test was performed in the overwrite/reproduction characteristic between the optical disk of the comparative example including a SiHfN layer having a refractive index of 1.95 and the optical disk of the embodiment including a SiHfON layer having a refractive index of 1.43 as the oxynitride dielectric layer 13. The details of the sample and comparative example of the optical disk used in this comparison test is as follows.

The layer structure of the optical disk of the comparative example included a 5-nm-thick ZnS—SiO₂ layer, a 46-nm-thick SiHfN layer, a 50-nm-thick ZnS—SiO₂ layer, a 5-nm-thick GeN layer, a 11-nm-thick GeSbTe layer, a 5-nm-thick GeN layer, a 46-nm-thick ZnS—SiO₂ layer and a 100-nm-thick AlTi layer, which are consecutively formed on a ZnS—SiO₂ substrate. The layer structure of the optical disk of the present embodiment included a 35-nm-thick ZnS—SiO₂ layer, a 40-nm-thick SiHfON layer, a 30-nm-thick ZnS—SiO₂ layer, a 5-nm-thick GeN layer a 11-nm-thick GeSbTe layer, a 5-nm-thick GeN layer, a 25-nm-thick ZnS—SiO₂ layer and a 100-nm-thick AlTi layer, which are consecutively formed on a ZnS—SiO₂ substrate.

The above sample optical disks are rotated at a liner velocity of 5.9 meters/second in the test, and iteratively subjected to overwrite/reproduction of a data signal having a frequency of 4 MHz and a duty ratio of 50% by using on optical head including an objective lens having a numerical aperture of 0.65 and irradiating a laser beam having a wavelength of 405 nm and a duty ratio of 50%. The number of times of overwrite/reproduction at which the reproduced signal is finally degraded by 1 decibel from the initially reproduced signal was obtained in the reproduction. The results of the test revealed that the optical disk of the embodiment including the SiHfON layer having a refractive index of 1.43 had no degradation in the reproduced signal before 500,000 times of overwrite/reproduction, whereas the optical disk of the comparative example including the SiHfN layer having a refractive index of 1.95 was degraded after about 30,000 times of overwrite/reproduction.

The results of the test are analyzed as follows. The overwrite/reproduction uses a laser beam, which irradiates the recording layer and thus causes a temperature rise in the recording layer. Since the SiHfN layer has a higher refractive index than the SiHfON layer, the third dielectric layer 18 in the comparative example has a thickness of 46 nm, which is larger than the thickness (25 nm) of the third dielectric layer 13 in the embodiment, in order for satisfying the relationship Aa<Ac in the optical absorption rate. Thus, the comparative example is subjected to a higher temperature rise in the recording layer 16 than the embodiment during the overwrite/reproduction, due to a larger heat resistance of the third dielectric layer 18 disposed between the recording layer 16 and the reflective layer 19 in the comparative example.

The higher temperature rise in the recording layer 16 degrades the overwrite/reproduction characteristic of the recording layer 16. In addition, the SiHfN layer has a relatively higher hardness and thus less flexibility, which may reduce the resistance against the thermal stress iteratively occurring in the SiHfN layer during the overwrite/reproduction, to thereby result in the signal deterioration.

Use of the SiHfN layer having a refractive index of 1.95 instead of the SiHfON layer does not cause the problem of a noise increase due to the lower film density, differently from the case of using a SiO₂ or Al₂O₃ layer as in the conventional technique. However, the use of the SiHfN layer incurs a smaller difference in the refractive index between the SiHfN layer and the first dielectric layer compared to the case of using the SiO₂ or Al₂O₃ layer. This largely restricts the thickness range of the third dielectric layer 18 in satisfying the relationship Aa<Ac for the optical absorption rate Aa in the amorphous phase of the recording layer 16 and the optical absorption rate Ac in the crystal phase of the recording layer 16. Thus, it was confirmed that the SiHfON layer is superior to the SiHfN layer in the design choice of the optical disk and the overwrite/reproduction characteristic of the optical disk.

In the comparative example, the SiHfN layer degraded the mass productivity and reliability of the optical disk. On the other hand, the SiHfON layer in the present embodiment achieves a higher mass productivity and reliability, in addition to the higher overwrite/reproduction characteristic as described above.

As understood from FIG. 3, the SiHfON layer formed in a mixed gas atmosphere including an Ar content of 90%, an O₂ content of 6% and the rest of N₂ also has a refractive index of around 1.95. This necessitates a larger thickness for the third dielectric layer to satisfy the above relationship, as in the case of the SiHfN layer. Thus, it is preferable to restrict the refractive index of the SiHfON layer 13 below around 1.9.

In the process of the above first example, the target used in the pulse DC sputtering included Si as the main component or base material thereof, and an additive Hf component added in the base material at a lat. %

### SECOND EXAMPLE

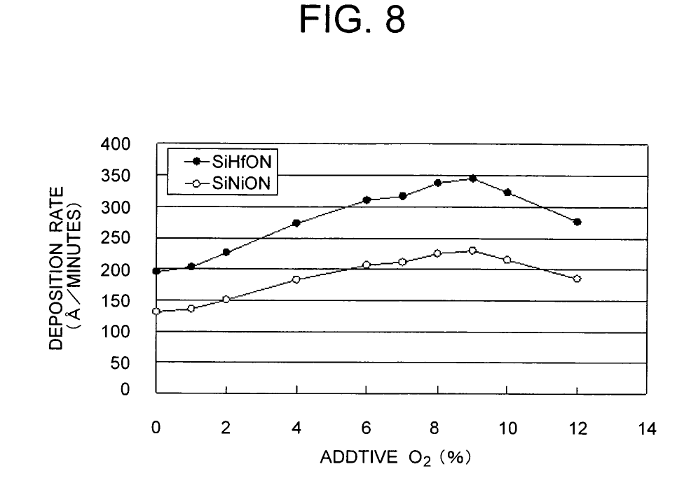

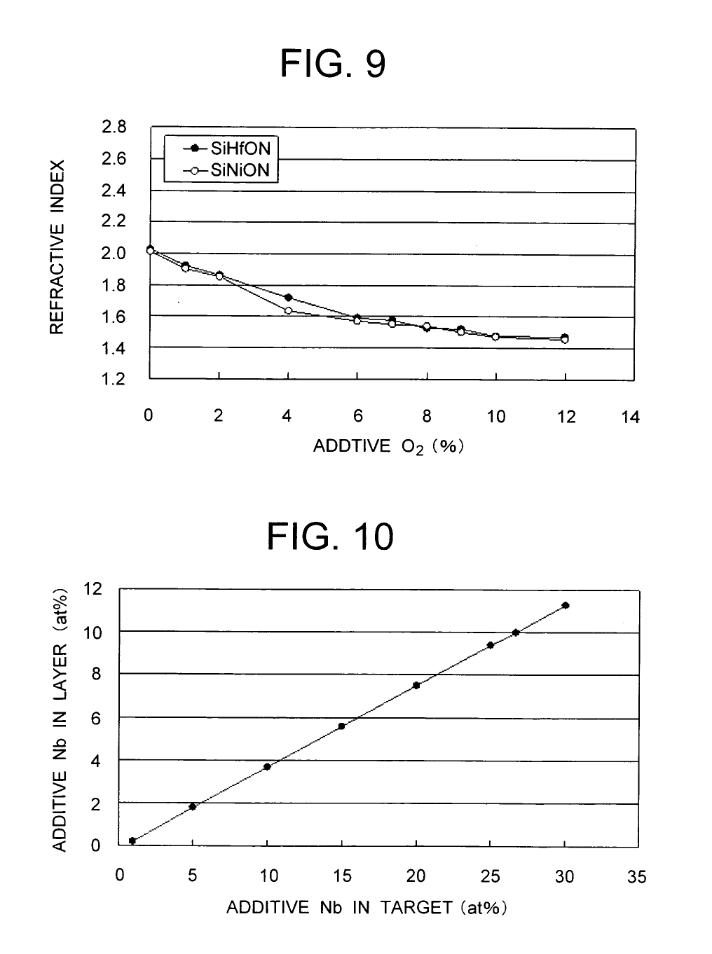

Second example used a pulse DC sputtering technique and a Si₉₉Hf₁ target to deposit the SiHfON layer. The process of the second example was compared against a conventional process using a RF sputtering technique, which used a Si₉₉Ni₁ target to deposit a SiNiON layer. FIG. 8 shows the deposition rate of both the SiHfON layer and SiNiON layer plotted on ordinate against the additive oxygen contents plotted on abscissa. FIG. 9 shows the refractive index of both the same SiHfON layer and SiNiON layer.

In the comparison, both the layers were formed in a mixed gas including an Ar content of 80% as a typical example. As understood from FIG. 8, the deposition rate of the SiHfON layer is about 1.5 times higher the deposition rate of the SiNiON layer. In the RF sputtering technique, most of the energy applied to the target is consumed as the heat energy, and thus does not contribute to accelerating the deposition rate. Thus, the RF sputtering technique has an inferior deposition rate compared to the pulse DC sputtering technique. On the other hand, as understood from FIG. 9, the refractive index of the SiHfON layer is roughly comparable to the refractive index of the SiNiON layer.

In the above example, the target included an additive Hf content in the Si base material to achieve a higher deposition rate and an equivalent refractive index compared to the conventional technique. However, such a phenomenon can be observed in a metallic element selected from the group consisting of Hf, Mn, Fe, Nb, Mo, Al, W and Ag. More specifically, the pulse DC sputtering process for depositing the oxynitride dielectric layer including such an additive element can achieve a higher deposition rate and an equivalent refractive index compared to the conventional RF sputtering technique for depositing the SiNiON layer.

Table 1 shows the deposition rate and refractive index (R.I.) of the oxynitride dielectric layers including the metallic elements of the group as recited above at lat. %, while being compared against those of the conventional SiNiON layer including Ni at lat. %. In Table 1, the top to bottom rows show the type of process for deposition, additive element in the target, deposition rate in the process, and the refractive index (R.I.) of the resultant layer, respectively.

TABLE 1

| | | | | | | | | | RF |
|---|---|---|---|---|---|---|---|---|---|
| Process | Pulse DC Sputtering | | | | | | | | Sputtering |
| Additive | Hf | Mn | Fe | Nb | Mo | Al | W | Ag | Ni |
| Deposition | 345.0 | 342.5 | 343.6 | 344.6 | 342.8 | 340.5 | 344.2 | 342.3 | 230.0 |
| Rate | | | | | | | | | |
| R.I. | 1.500 | 1.524 | 1.516 | 1.508 | 1.516 | 1.530 | 1.513 | 1.525 | 1.503 |

As understood from Table 1, the oxynitride dielectric layers including the additives as recited above at lat. % have a superior deposition rate and a refractive index comparable to the refractive index of the conventional SiNiON layer.

In the first and second examples, the effectiveness of the additive elements in the oxynitride dielectric layers including the additive elements at lat. % was examined. In the following third to fifth examples, the content or amount of additive elements added in the Si base material was examined. Those examples revealed that the content of additive elements is preferably within a range between 0.2 at. % and 10 at. % in the oxynitride dielectric layer.

### THIRD EXAMPLE

Targets used in a third example are prepared by adding the metallic elements of the group as recited above in a Si base material. The rate of additive elements was varied between zero at. % and 30 at. % for each of the additive elements. The targets thus obtained were used in the pulse DC sputtering process for depositing the oxynitride dielectric layers, and the resultant oxynitride dielectric layers were examined as to the relationship between the content of additive elements in the target and the content of the additive elements in the oxynitride dielectric layer, and the relationship between the deposition rate as well as the refractive index and the content of the additive elements in the oxynitride dielectric layers.

FIG. 10 shows the relationship between the content (%) of additive Nb in the target used in the pulse DC sputtering and the content (%) of additive Nb in the resultant oxynitride dielectric layer. As shown in FIG. 10, a Si₉₉Nb₁ target used in the sputtering provided a SiNbON layer including a Nb content of 0.2 at. %, and a Si₇₀Nb₃₀ target used in the sputtering provided a SiNbON layer having a Nb content of 11.3 at. %. On the other hand, the film property of the SiNbON layer was scarcely changed within the range of zero to 11.3 at. % of the additive Nb content in the SiNbON layer. This tendency is common in the group of the elements recited above.

However, it was noted that a specific range of additive content has a significant influence on the recording sensitivity of the optical disk including the oxynitride third dielectric layer 13 and on the optical reflectivity thereof after the environmental test of the optical disk. The configurations of the optical disks used in the procedure of the following examples were similar to those of the first embodiment except for the component and proportion of the oxynitride third dielectric layer 13.

In the third example, Nb was selected as the additive element in the target, which was employed in the sputtering to form sample SiNbON layers including Nb content of zero to 11.3 at. %. The sample SiNbON layers thus obtained were subjected to the environmental test, wherein these samples were stored in a thermostatic bath maintained at a temperature of 80 degrees C. and a humidity of 90% for 3000 hours. The samples were subjected to measurement of optical reflectivity before and after storage thereof in the thermostatic bath, for obtaining the change of reflectivity (ΔR, in percent) therebetween.

Table 2 shows the change of reflectivity ΔR and the Nb content in the SiNbON layer, as well as the recording sensitivity of the optical disk expressed in terms of recording power, Nb content in the target. The recording sensitivity of the optical disk is expressed by an optimum recording power for recording data on the recording layer. The top to bottom rows of Table 2 show the Nb content (x) in the target, Nb content (y) in the oxynitride dielectric layer, change of the optical reflectivity (ΔR) and the optimum recording power thereof, respectively.

TABLE 2

| | | | | | | | | | | |
|---|---|---|---|---|---|---|---|---|---|---|
| Nb (x) | 0 | 1 | 5 | 10 | 15 | 20 | 25 | 26.7 | 28 | 30 |
| Nb (y) | 0 | 0.2 | 1.8 | 3.7 | 5.6 | 7.5 | 9.4 | 10 | 10.8 | 11.3 |
| ΔR | 0.3 | 0 | 0 | 0 | 0 | 0 | 0 | 0 | 0 | 0 |
| Power | 5.4 | 5.4 | 5.4 | 5.4 | 5.4 | 5.4 | 5.5 | 5.5 | 6.0 | 6.7 |

In general, the optical disk should preferably have a smaller difference ΔR in the optical reflectivity between before and after the environmental test, and a higher recording sensitivity, i.e., a smaller optimum recording power. Table 2 reveals that the preferable Nb content in the SiNbON layer resides in the range of 0.2 to 11.3 at. % in the view point of ΔR, and resides in the range of zero to 10 at. % in the view point of the optimum recording power.

For achieving both the characteristics, as understood from Table 2, the Nb content in the SiNbON layer should preferably reside in the range of 0.2 to 10 at. %. In addition, for obtaining such a range of the Nb content in the SiNbON layer, the additive Nb content in the target used for the sputtering should reside in the range of 1 to 26.7 at. %.

### FOURTH EXAMPLE

In the fourth example, Hf was selected as the additive element in the target, wherein the Hf content in the SiHfON layer was varied in the range of zero to 11.3 at. % and sample optical disks including such a SiHfON layer were subjected to the environment test. The environment test was such that the samples were stored in a thermostatic bath at a temperature of 80 degrees C. and a humidity of 90% for 3000 hours, and the difference in the optical reflectivity between before and after the environmental test was measured for the samples. Table 3 shows the results of the environmental test for optical disk including the SiHfON layers similarly to Table 2.

TABLE 3

| | | | | | | | | | | |
|---|---|---|---|---|---|---|---|---|---|---|
| Hf (x) | 0 | 1 | 5 | 10 | 15 | 20 | 25 | 26.7 | 28 | 30 |
| Hf (y) | 0 | 0.2 | 2.0 | 3.5 | 5.5 | 7.4 | 9.8 | 10 | 11.2 | 11.5 |
| ΔR | 0.5 | 0 | 0 | 0 | 0 | 0 | 0 | 0 | 0 | 0 |
| Power | 5.3 | 5.3 | 5.3 | 5.3 | 5.3 | 5.3 | 5.3 | 5.4 | 6.1 | 6.6 |

As understood from Table 3, the preferable Hf content in the SiHfON layer resides within the range of 0.2 to 11.5 at. % in the view point of ΔR, and resides within the range of zero to 10 at. % in the view point of the recording power. For achieving both the characteristics, the Hf content in the SiHfON layer should preferably reside in the range of 0.2 to 10 at. %. In addition, for obtaining such a range of the Hf content in the SiHfON layer, the additive Hf content in the target used for the sputtering should reside in the range of 1 to 26.7 at. %.

### FIFTH EXAMPLE

In the fifth example, Mo was selected as the additive element in the target, wherein the Mo content in the SiMoON layer was varied in the range of zero to 11.3 at. % and sample optical disks including such a SiHfON layer were subjected to the environment test. The environment test was such that the samples were stored in a thermostatic bath at a temperature of 80 degrees C. and a humidity of 90% for 3000 hours, and the difference in the optical reflectivity between before and after the environmental test was measured for the samples. Table 4 shows the results of the environmental test for optical disk including the SiMoON layers similarly to Table 2.

TABLE 4

| | | | | | | | | | | |
|---|---|---|---|---|---|---|---|---|---|---|
| Mo (x) | 0 | 1 | 5 | 10 | 15 | 20 | 25 | 26.7 | 28 | 30 |
| Mo (y) | 0 | 0.2 | 1.7 | 3.4 | 5.8 | 7.2 | 9.6 | 10 | 11.0 | 11.4 |
| ΔR | 0.2 | 0 | 0 | 0 | 0 | 0 | 0 | 0 | 0 | 0 |
| Power | 5.4 | 5.4 | 5.4 | 5.4 | 5.4 | 5.4 | 5.4 | 5.4 | 5.8 | 6.3 |

As understood from Table 4, the preferable Mo content in the SiMoON layer resides within the range of 0.2 to 11.4 at. % in the view point of ΔR, and resides within the range of zero to 10 at. % in the view point of the recording power. For achieving both the characteristics, the Mo content in the SiMoON layer should preferably reside in the range of 0.2 to 10 at. %. In addition, for obtaining such a range of the Hf content in the SiMoON layer, the additive Mo content in the target used for the sputtering should reside in the range of 1 to 26.7 at. %.

Other metallic elements including Mn, Fe, Al, W and Ag were used for the additive elements in the target, similarly to the third to fifth examples, providing similar results wherein the content of additive elements residing in the range of 1 to 26.6 at. % in the target achieved the advantages of substantially unchanged optical reflectivity after the environmental test and the higher recording sensitivity for the optical disk. In addition, it was confirmed that the optimum content of additive elements in the oxynitride dielectric layer 13 resides in the rage of 0.2 to 10 at. %.

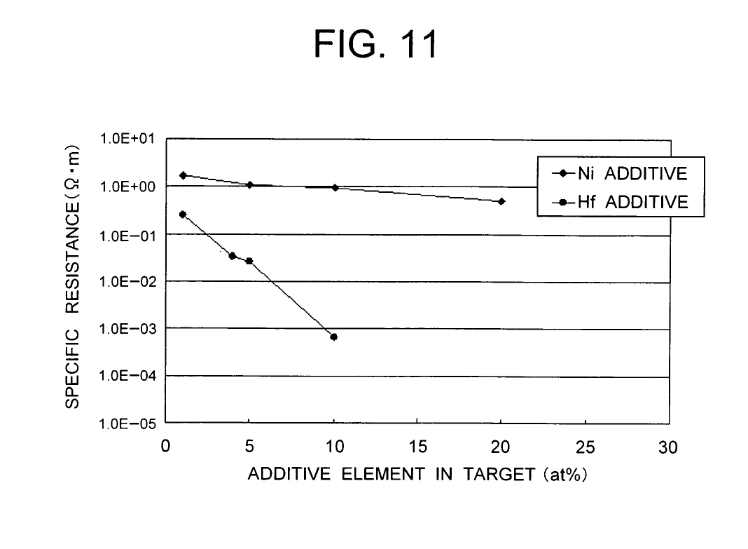

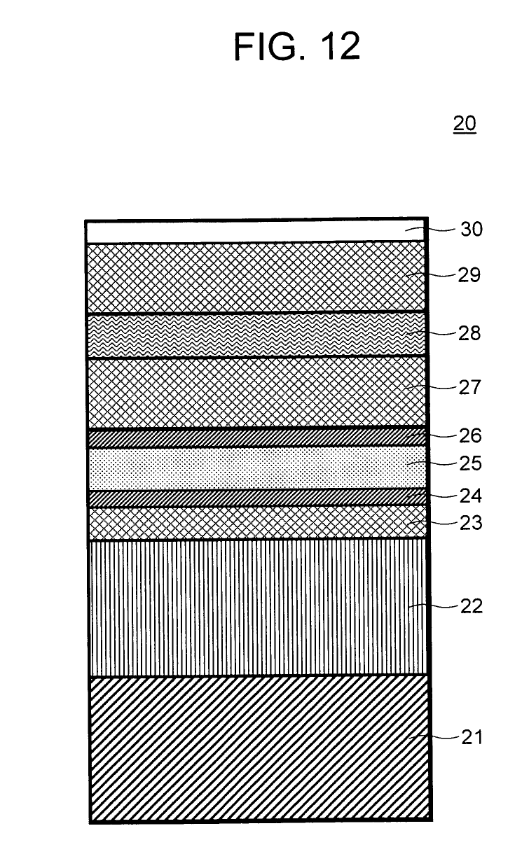

FIG. 11 shows the relationship between the content of the above additive element, Hf, in a Si base material and the specific resistance of the resultant target including the additive Hf. For a comparison purpose, the case of additive element being Ni is also shown in FIG. 11. Addition of Hf in the target significantly reduces the specific resistance of the target down to below 1 Ω-cm, which causes a stable discharge in the pulse DC sputtering process. This tendency is common to other materials of the group consisting of Hf, Mn, Fe, Nb, Mo, Al, W and Ag.

On the other hand, addition of Ni in the target scarcely reduces the specific resistance of the target, and does not provide a specific resistance of 1 Ω-cm or lower until the content of Ni exceeds 10 at. %. Thus, the pulse DC sputtering technique is difficult to employ in the range of Ni content being lower than 10 at. %, and the RF sputtering is essential in this range. However, the RF sputtering uses the energy of the electric power applied to the target mostly in a thermal energy, and thus the applied energy scarcely contributes to accelerating the deposition rate.

It was thus confirmed that the addition of the metallic elements in the above group in the Si base material of the target improves the deposition rate in the pulse DC sputtering.

The optical disks used in the first through fifth examples belonged to the type in which the laser beam is incident onto the side of the substrate on which the layers are deposited, i.e., substrate-incident type. However, similar results can be also obtained in a transparent-film-incident type in which the laser beam is incident onto a transparent film adhered onto top of the layers deposited on the substrate. The transparent-film-incident type to which the present invention is applied will be described hereinafter.

FIG. 12 shows an optical disk according to a second embodiment of the present invention, which is known as a transparent-film-incident type. The oxynitride dielectric layer in the optical disk is configured by a SiNbON layer.

More specifically, the optical disk, generally designated by numeral 20, includes a substrate 21, and a layer structure including a reflective layer 22, a first dielectric layer 23, a first interface layer 24, a recording layer 25, a second interface layer 26, a second dielectric layer 27, the oxynitride dielectric layer 28, and a third dielectric layer 29, which are consecutively sputtered onto the substrate 21. A transparent film 30 is bonded onto the third dielectric layer 29.

The laser beam for recording/reproducing data is incident onto the optical disk through the transparent film 30. Each of the layers may be configured by a single-film layer or a multiple-film layer.

The substrate 21 may be made of plastic, resin or glass, and is 1.1 mm thick, for example. The substrate 21 may be transparent or opaque, because the laser beam is not incident onto the substrate 21.

The first through third dielectric layers 23, 27, 29 are made of ZnS—SiO₂, for example. The oxynitride dielectric layer 28 may is of SiNbON, which is sputtered onto the second dielectric layer 27 by using a reactive-ion sputtering process. The oxynitride dielectric layer 28 includes 39 to 67.5 at. % oxygen. The first and second interface layers 24, 26 are made of GeN. The recording layer 25 may be made of Ge₂Sb₂Te₅, the reflective layer 22 may be made of AlTi, and the transparent film 30 may be made of polycarbonate having a thickness of 0.1 mm, for example.

The optical absorption rate Aa in the amorphous phase of the recording layer 25 is set lower than the optical absorption rate in the crystal phase of the recording layer 25. For achieving this relationship Aa<Ac, the refractive index of the layers is designed as detailed hereinafter. The transparent film 30 generally has a refractive index of around 1.5 to 1.6. The third dielectric layer 29 should have a higher refractive index for achieving the above relationship. If the third dielectric layer 29 has a refractive index equivalent to the refractive index of the transparent film 30, the third dielectric layer 29 and transparent film 30 are optically equivalent to each other and do not provide such a relationship. The third dielectric layer 29 has a suitable adhesion characteristic with respect to the transparent film 30. This characteristic is achieved in the third dielectric layer 29 being made of ZnS—SiO₂, and thus the first and second dielectric layers are also made of ZnS—SiO₂ having a refractive index of around 2.5.

The oxynitride dielectric layer configured by SiNbON has a refractive index of around 1.43 to 1.8. This allows the refractive index (n28) of the oxynitride dielectric layer 28 and the refractive index (n27) of the second dielectric layer 27 to satisfy therebetween the relationship n28<n27, and the refractive index n28 of the oxynitride dielectric layer 28 and the refractive index (n29) of the third dielectric layer 29 to satisfy therebetween the relationship n29>n28. Thus, the relationship Aa<Ac can be achieved.

The oxygen content and additive Nb content of the SiNbON configuring the oxynitride dielectric layer 28 reside within the range as described in connection with the first embodiment. This is because the function of the layers is similar in the first and second embodiments, although the order of the deposition is different between the substrate-incident-type in the first embodiment and the transparent-film-incident-type in the second embodiment.

It will be thus apparent that the Nb in the oxynitride dielectric layer may be replaced by other metallic elements belonging to the above group described in the first embodiment.

The deposition technique used for the above layers may be varied depending on the desired recording/reproducing characteristic and/or the intended purpose of the optical disk, so long as the relationship Aa<Ac is satisfied without degrading the deposition rate. In addition, the thickness and/or material for the transparent substrate, transparent film, and other layers may be selected as desired.

Although the gas pressure of the reactive-ion sputtering for depositing the SiNbON layer is exemplified as 0.2 Pa, the gas pressure may be selected from the range of 0.09 to 0.5 Pa. The process for forming the layers on the substrate may be performed by the in-line processing as described above, or a batch processing in which a plurality of optical disks are manufactured in a batch.

Since the above embodiments are described only for examples, the present invention is not limited to the above embodiments and various modifications or alterations can be easily made therefrom by those skilled in the art without departing from the scope of the present invention.

What is claimed is:

1. A phase-change optical disk comprising a substrate, and a layer structure overlying said substrate and including an oxynitride dielectric layer and a recording layer, wherein said oxynitride dielectric layer includes an oxynitride substance including silicon as a main component thereof and at least one additive element selected from the group consisting of Hf, Mn, Fe, Nb, Mo, Al, W and Ag.

2. The phase-change optical disk according to claim 1, wherein said oxynitride substance includes oxygen at 39 to 67.5 atomic percents.

3. The phase-change optical disk according to claim 1, wherein said oxynitride substance has a refractive index of 1.43 to 1.8.

4. The phase-change optical disk according to claim 1, wherein said oxynitride substance includes said additive element at 0.2 to 10 atomic percents.

5. The phase-change optical disk according to claim 1, wherein:
said substrate is a transparent substrate;
said layer structure includes a first dielectric layer, said oxynitride dielectric layer, a second dielectric layer, said recording layer, a third dielectric layer and a reflective layer, which are consecutively formed on said transparent substrate; and
said reflective layer reflects incident light passed by said transparent substrate, said oxynitride dielectric layer, said recording layer and said first through third dielectric layers toward said recording layer.

6. The optical disk according to claim 5, wherein a refractive index of each of said first and second dielectric layers is larger than a refractive index of said oxynitride dielectric layer.

7. The optical disk according to claim 1, wherein:
said layer structure includes a reflective layer, a first dielectric layer, said recording layer, a second dielectric layer, said oxynitride dielectric layer, a third dielectric layer, and a transparent film which are consecutively formed on said substrate; and
said reflective layer reflects incident light passed by said transparent film, said oxynitride dielectric layer, said recording layer and said first through third dielectric layers toward said recording layer.

8. The optical disk according to claim 7, wherein a refractive index of each of said second and third dielectric layers is larger than a refractive index of said oxynitride dielectric layer.

9. A method for manufacturing a phase-change optical disk comprising forming a layer structure including a oxynitride dielectric layer and a recording layer on a substrate, wherein:
forming the oxynitride dielectric layer is performed by a reactive-ion sputtering in a mixed gas atmosphere including argon, oxygen and nitrogen; and
said reactive-ion sputtering uses a target including silicon as a main component thereof and at least one additive element selected from the group consisting of Hf, Mn, Fe, Nb, Mo, Al, W and Ag.

10. The method according to claim 9, wherein said mixed gas has a composition defined on a ternary diagram of argon, oxygen and nitrogen by a hexagon having apexes of (90, 9, 1), (80, 12, 8), (70, 12, 18), (70, 2, 28), (80, 3, 17) and (90, 7, 3), and the internal of the hexagon, all of the three values between the parentheses being expressed in terms of volume percents of argon, oxygen and nitrogen in this order.

11. The method according to claim 9, wherein said target includes said at least one additive element at 1 to 26.7 atomic percents.

12. A method for manufacturing a phase-change optical disk comprising consecutively:
forming a first dielectric layer overlying a transparent substrate;
forming an oxynitride dielectric layer on said first dielectric layer by using a reactive-ion sputtering in a mixed gas atmosphere including argon, oxygen and nitrogen; and
consecutively forming, on said oxynitride layer, a second dielectric layer, a recording layer, a third dielectric layer, and a reflective layer,
wherein said reactive-ion sputtering uses a target including silicon as a main component thereof and at least one additive element selected from the group consisting of Hf, Mn, Fe, Nb, Mo, Al, W and Ag.

13. A method for manufacturing a phase-change optical disk comprising:
consecutively forming a reflective layer, a first dielectric layer, a recording layer, and a second dielectric layer to overlie a substrate;
forming an oxynitride dielectric layer on said second dielectric layer by using reactive-ion sputtering in a mixed gas atmosphere including argon, oxygen and nitrogen; and
consecutively forming a third dielectric layer and a transparent film on said oxynitride dielectric layer,
wherein said reactive-ion sputtering uses a target including silicon as a main component thereof and at least one additive element selected from the group consisting of Hf, Mn, Fe, Nb, Mo, Al, W and Ag.
